(19) United States
(12) Patent Application Publication
(10) Pub. No.: US 2026/0113836 A1
(43) Pub. Date: Apr. 23, 2026

(54) SEMICONDUCTOR DEVICE INCLUDING SLOT ON PERIPHERAL REGION OF SUBSTRATE

(71) Applicant: NANYA TECHNOLOGY CORPORATION, NEW TAIPEI CITY (TW)

(72) Inventor: WU-DER YANG, NEW TAIPEI CITY (TW)

(21) Appl. No.: 18/918,373

(22) Filed: Oct. 17, 2024

(51) Int. Cl. H01L 23/00; H01L 23/31; H05K 1/02; H05K 1/18

(52) U.S. Cl. CPC H05K 1/0284; H05K 1/181; H10W 74/114; H05K 2201/10287; H10W 74/00; H10W 90/754

(57) ABSTRACT

A semiconductor device and method for manufacturing the same are provided. The semiconductor device includes a substrate, an electronic component, and an encapsulant. The substrate has a lower surface and an upper surface opposite to the lower surface. The electronic component is disposed on the upper surface of the substrate. The encapsulant is disposed on the upper surface of the substrate. The encapsulant includes a first portion penetrating the substrate at a central region of the substrate and a second portion penetrating the substrate at a peripheral region of the substrate.

### TECHNICAL FIELD

The present disclosure relates to a semiconductor device and a method for manufacturing the same, and more particularly, to a semiconductor device including slots on the peripheral region of a substrate.

### DISCUSSION OF THE BACKGROUND

With the rapid growth of the electronics industry, integrated circuits (ICs) have achieved high performance and miniaturization. Technological advances in IC materials and design have produced generations of ICs in which each successive generation has smaller and more complex circuits.

Many techniques have been developed to increase the performance of semiconductor devices. For example, a decoupling capacitor structure may be utilized to filter signals with a specific frequency. However, such decoupling capacitor structures may occupy additional areas, which increases the size of a semiconductor device. Therefore, improved semiconductor devices and methods of solving such problems are required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, an electronic component, and an encapsulant. The substrate has a lower surface and an upper surface opposite to the lower surface. The electronic component is disposed on the upper surface of the substrate. The encapsulant is disposed on the upper surface of the substrate. The encapsulant includes a first portion penetrating the substrate at a central region of the substrate and a second portion penetrating the substrate at a peripheral region of the substrate.

Another aspect of the present disclosure provides another semiconductor device. The semiconductor device includes a substrate, an electronic component, a first pad, a second pad, a first conductive wire, and a second conducive wire. The substrate has a lower surface and an upper surface opposite to the lower surface. The first pad is disposed on the lower surface and at a central region of the substrate. The second pad is disposed on the lower surface and at a peripheral region of the substrate. The electronic component is disposed on the upper surface of the substrate. The first conductive wire passes through the central region of the substrate to electrically connect the electronic component and the first pad. The second conductive wire passes through the peripheral region of the substrate to electrically connect the electronic component and the second pad.

Another aspect of the present disclosure provides a method of manufacturing a semiconductor device. The method includes: providing a substrate having a lower surface and an upper surface opposite to the first surface, wherein the substrate has a first slot at a central region and a second slot at a peripheral region of the substrate; forming an electronic component on the upper surface of the substrate; and forming an encapsulant to encapsulate the electronic component, and the encapsulant has a first portion filling the first slot and a second portion filling the second slot.

In an advantageous semiconductor device, power pads (and a portion of I/O pads) are arranged at the peripheral region of a substrate. To reduce the power path and address packaging issues, one or more slots can be formed on the peripheral region of the substrate. The locations of the slots depend on the location of the power pads (or I/O pads). In this embodiment, the process is relatively simple, and the power path can be reduced, resulting in enhanced performance of the semiconductor device.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a bottom view of a semiconductor device, in accordance with some embodiments of the present disclosure.

FIG. 1B is a cross-sectional view along line A-A' of the semiconductor device as shown in FIG. 1A, in accordance with some embodiments of the present disclosure.

FIG. 2 is a bottom view of a semiconductor device, in accordance with some embodiments of the present disclosure.

FIG. 3 is a flowchart illustrating a method of manufacturing a semiconductor device, in accordance with some embodiments of the present disclosure.

FIG. 4A illustrates one or more stages of an exemplary method for manufacturing a semiconductor device according to some embodiments of the present disclosure.

FIG. 4B is a cross-sectional view along line A-A' of the stage as shown in FIG. 4A, in accordance with some embodiments of the present disclosure.

FIG. 5A illustrates one or more stages of an exemplary method for manufacturing a semiconductor device according to some embodiments of the present disclosure.

FIG. 5B is a cross-sectional view along line A-A' of the stage as shown in FIG. 5A, in accordance with some embodiments of the present disclosure.

FIG. 6A illustrates one or more stages of an exemplary method for manufacturing a semiconductor device according to some embodiments of the present disclosure.

FIG. 6B is a cross-sectional view along line A-A' of the stage as shown in FIG. 6A, in accordance with some embodiments of the present disclosure.

FIG. 7A illustrates one or more stages of an exemplary method for manufacturing a semiconductor device according to some embodiments of the present disclosure.

FIG. 7B is a cross-sectional view along line A-A' of the stage as shown in FIG. 7A, in accordance with some embodiments of the present disclosure.

FIG. 8A illustrates one or more stages of an exemplary method for manufacturing a semiconductor device according to some embodiments of the present disclosure.

FIG. 8B is a cross-sectional view along line A-A' of the stage as shown in FIG. 8A, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

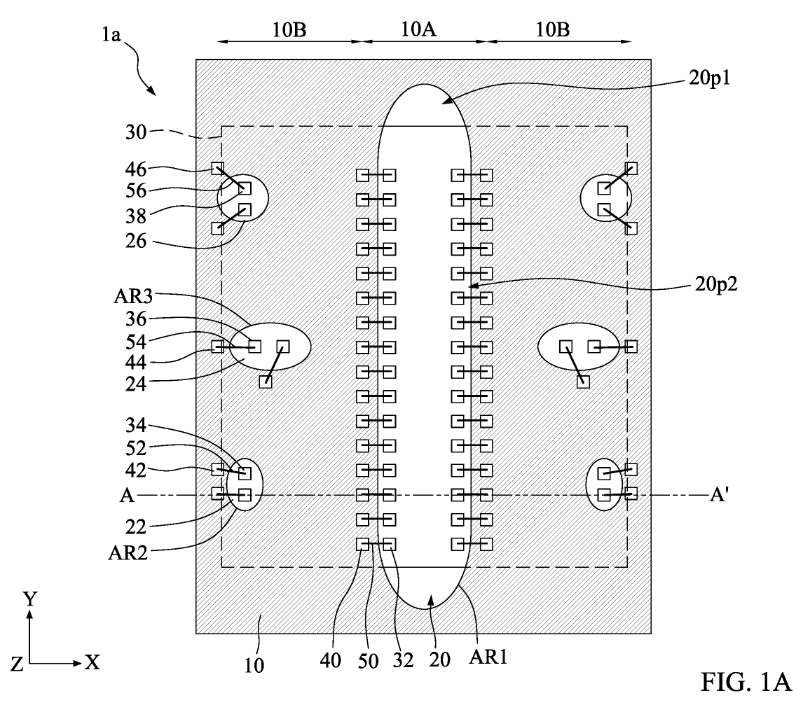

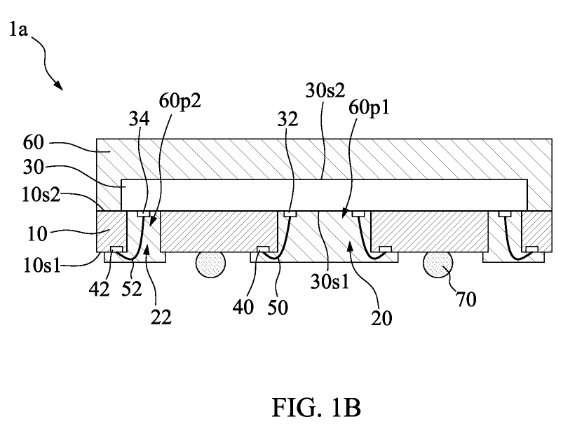

FIG. 1A and FIG. 1B illustrate a semiconductor device 1a, in accordance with some embodiments of the present disclosure. FIG. 1A is a top view. FIG. 1B is a cross-sectional view along line A-A' of FIG. 1A. In some embodiments, the semiconductor device 1a may include a double data rate fifth-generation (DDR5) synchronous dynamic random-access memory or its derivative devices. It should be noted that some of the features are omitted from FIG. 1A for brevity.

In some embodiments, the semiconductor device 1a may include a substrate 10. In some embodiments, the substrate 10 may be or include, for example, a printed circuit board (PCB), such as a paper-based copper foil laminate, a composite copper foil laminate, or a polymer-impregnated glass-fiber-based copper foil laminate.

In some embodiments, the substrate 10 may include a surface 10s1 and a surface 10s2 opposite to the surface 10s1. In some embodiments, the surface 10s1 may also be referred to as a lower surface. In some embodiments, the surface 10s2 may also be referred to as an upper surface.

In some embodiments, the substrate 10 may include conductive pad(s), trace(s), via(s), layer(s), or other interconnection(s) therein and abutting surface 10s1 and/or surface 10s2. For example, the substrate 10 may include one or more transmission lines (e.g., communications cables) and one or more grounding lines and/or grounding planes therein.

In some embodiments, the substrate 10 may include a central region 10A and a peripheral region 10B. The peripheral region 10B may surround the central region 10A. The peripheral region 10B may be disposed on two opposite sides of the central region 10A along the X direction. In some embodiments, the central region 10A may be a region on which a main slot and conductive wires, passing through the main slot, are disposed. In some embodiments, the peripheral region 10B may be a region of the substrate 10 that the central region 10A is excluded. In some embodiments, the peripheral region 10B may be a region on which side slots are disposed.

In some embodiments, the substrate 10 may define an opening 20 (or main slot or main aperture). In some embodiments, the opening 20 may be disposed at the central region 10A of the substrate 10. The opening 20 may have longer edges extending along the Y direction and shorter edges disposed on two opposite sides of the longer edge. In some embodiments, the opening 20 may have terminal portions 20p1 on opposite sides of the longer edge. The terminal portion 20p1 may have a curved profile (e.g., semi-sphere profile) or other suitable profiles. The opening 20 may have a central portion 20p2 extending between two terminal portions 20p1. In some embodiments, the central portion 20p2 may have a substantial uniform width along the X direction. In some embodiments, the width W1 of the central portion 20p2 of the opening 20 may be greater than 1100um, such as 1100um, 1200um, 1300um, 1400um, 1500um, or more. In some embodiments, the opening 20 may be configured to allow a molding material (or encapsulant material) to pass through during forming an encapsulant. In some embodiments, the opening 20 may also be referred to as an encapsulant-injection slot.

In some embodiments, the substrate 10 may define openings 22, 24, and 26 (or side slots or side apertures). Each of the openings 22, 24, and 26 may be disposed at the peripheral region 10B of the substrate 10. Each of the openings 22, 24, and 26 is closer to the edge, which extends along the Y direction, of the substrate 10 than the opening 20 is. In some embodiments, the locations of the openings 22, 24, and 26 may depend on the locations of the pads of the electronic component 30. In some embodiments, the locations of the openings 22, 24, and 26 may depend on the pads of the substrate 10.

Each of the openings 22, 24, and 26 may have a dimension (e.g., area, profile, or the like) different from that of the opening 20. For example, the opening 20 has an area AR1, the opening 22 has an area AR2 different from the area AR1. In some embodiments, the area AR2 may be less than the area AR1. For example, the opening 24 has an area AR3 different from the area AR1. In some embodiments, the area AR3 may be less than the area AR1. In some embodiments, the area AR3 of the opening 24 may be different from the area AR2 of the opening 22. In some embodiments, the profile of the opening 22 may be different from the profile of the opening 20. In some embodiments, the profile of the opening 24 may be different from the profile of the opening 22. In some embodiments, a portion of the opening 26 may be free from overlapping the electronic component 30.

In some embodiments, the semiconductor device 1a may include an electronic component 30. The electronic component 30 may be disposed on or over the surface 10s2 of the substrate 10. In some embodiments, the electronic component 30 may cover the opening 20. In some embodiments, the terminal portion 20p1 of the opening 20 may be exposed by the electronic component 30. In some embodiments, the central portion 20p2 of the opening 20 may be covered by the electronic component 30.

The electronic component 30 may include a memory device, such as a dynamic random access memory (DRAM) device, a one-time programming (OTP) memory device, a static random access memory (SRAM) device, or other suitable memory devices. In some embodiments, the electronic component 30 may include a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices), or other devices.

In some embodiments, the electronic component 30 may be attached to the substrate 10 by an adhesive (not shown). In some embodiments, the adhesive may include a die attach film (DAF) or other suitable materials.

In some embodiments, the electronic component 30 may have a surface 30s1 facing the substrate 10 and a surface 30s2 opposite to the surface 30s1. However, the present disclosure is not intended to be limiting. In some embodiments, the surface 30s1 may be a lower surface of the electronic component 30, and the surface 30s2 may be an upper surface of the electronic component 30.

The electronic component 30 may include pads 32, 34, 36, and 38. The pad 32 may be disposed on or under the surface 30s1 of the electronic component 30. In some embodiments, the pad 32 may be disposed at the central region 10A and exposed by the opening 20. The pad 34 may be disposed on or under the surface 30s1 of the electronic component 30. In some embodiments, the pad 34 may be disposed at the peripheral region 10B and exposed by the opening 22. The pad 36 may be disposed on or under the surface 30s1 of the electronic component 30. In some embodiments, the pad 36 may be disposed at the peripheral region 10B and exposed by the opening 24. The pad 38 may be disposed on or under the surface 30s1 of the electronic component 30. In some embodiments, the pad 38 may be disposed at the peripheral region 10B and exposed by the opening 26.

The substrate 10 may have the pads 40, 42, 44, and 46. The pads 40, 42, 44, and 46 may be disposed on or under the surface 10s1 of the substrate 10. In some embodiments, the pad 40 may be disposed within the central region 10A and configured to transmit a non-power signal (e.g., an input/output (e.g., I/O) signal). In some embodiments, the pads 42, 44, and 46 may be disposed within the peripheral region 10B and configured to transmit a power signal or a non-power signal.

In some embodiments, the semiconductor device 1a may include conductive wires 50, 52, 54, and 56 (or bonding wires). The conductive wire 50 may be disposed on or under the surface 10s1 of the substrate 10. In some embodiments, the conductive wire 50 may be disposed at the central region 10A of the substrate 10. In some embodiments, the conductive wire 50 may pass through the opening 20. The conductive wire 50 may connect the pads 32 and 40. In some embodiments, the conductive wire 50 may be configured to transmit a non-power signal, such as an I/O signal.

The conductive wire 52 may be disposed on or under the surface 10s1 of the substrate 10. In some embodiments, the conductive wire 52 may be disposed at the peripheral region 10B of the substrate 10. In some embodiments, the conductive wire 52 may pass through the opening 22. The conductive wire 50 may connect the pads 34 and 42. The conductive wire 54 may be disposed on or under the surface 10s1 of the substrate 10. In some embodiments, the conductive wire 54 may be disposed at the peripheral region 10B of the substrate 10. In some embodiments, the conductive wire 54 may pass through the opening 24. The conductive wire 54 may connect the pads 36 and 44. The conductive wire 56 may be disposed on or under the surface 10s1 of the substrate 10. In some embodiments, the conductive wire 56 may be disposed at the peripheral region 10B of the substrate 10. In some embodiments, the conductive wire 56 may pass through the opening 26. The conductive wire 56 may connect the pads 38 and 46. In some embodiments, the conductive wire 52, 54, and/or 56 may be configured to transmit a power signal. In some embodiments, the conductive wire 52, 54, and/or 56 may be electrically connected to ground. In some embodiments, the conductive wire 52, 54, and/or 56 may be configured to transmit a non-power signal.

In some embodiments, the conductive wires 50, 52, 54, and 56 may include metal, such as copper (Cu), silver (Ag), gold (Au), nickel (Ni), aluminum (Al), alloys thereof, combinations thereof, or other suitable materials.

In some embodiments, the semiconductor device 1a may include an encapsulant 60 (or a molding compound). In some embodiments, the encapsulant 60 may be disposed on or under the surface 10s1 of the substrate 10. A portion of the surface 10s1 may be exposed by the encapsulant 60. In some embodiments, the encapsulant 60 may be disposed on or over the surface 10s2 of the substrate 10. In some embodiments, the encapsulant 60 may encapsulate the electronic component 30. In some embodiments, the encapsulant 60 may encapsulate the conductive wire 50. In some embodiments, the encapsulant 60 may encapsulate the conductive wire 52. In some embodiments, the encapsulant 60 may encapsulate the conductive wire 54. In some embodiments, the encapsulant 60 may encapsulate the conductive wire 56.

As shown in FIG. 1B, a portion 60p1 of the encapsulant 60 may be disposed within the opening 20. In some embodiments, the portion 60p1 may penetrate the substrate 10. In some embodiments, the electronic component 30 may cover or vertically overlap the portion 60p1. In some embodiments, a portion 60p2 of the encapsulant 60 may be disposed within the opening 22. In some embodiments, the portion 60p2 may penetrate the substrate 10. In some embodiments, the area of the portion 60p2 may be different from that of the portion 60p1. In some embodiments, the portion 60p2 of the encapsulant 60 may be free from vertically overlapping the electronic component 30.

In some embodiments, the encapsulant 60 may be made of molding material that may include, for example, a novolac-based resin, an epoxy-based resin, a silicone-based resin, or another suitable encapsulant. Suitable fillers may also be included, such as powdered SiO₂.

In some embodiments, the semiconductor device 1a may include electrical connectors 70. In some embodiments, the electrical connectors 70 may be disposed on or under the surface 10s1 of the substrate 10. The electrical connectors 70 may be configured to provide an external connection. The electrical connectors 70 may be electrically connected an external device. The electrical connectors 70 may include a solder material, such as alloys of gold and tin solder or alloys of silver and tin solder.

In an advantageous semiconductor device, power pads (and a portion of I/O pads) are arranged at the peripheral region of a substrate. To reduce the power path and address packaging issues, one or more slots can be formed on the peripheral region of the substrate. The locations of the slots depend on the location of the power pads (or I/O pads). In this embodiment, the process is relatively simple, and the power path can be reduced, resulting in enhanced performance of the semiconductor device.

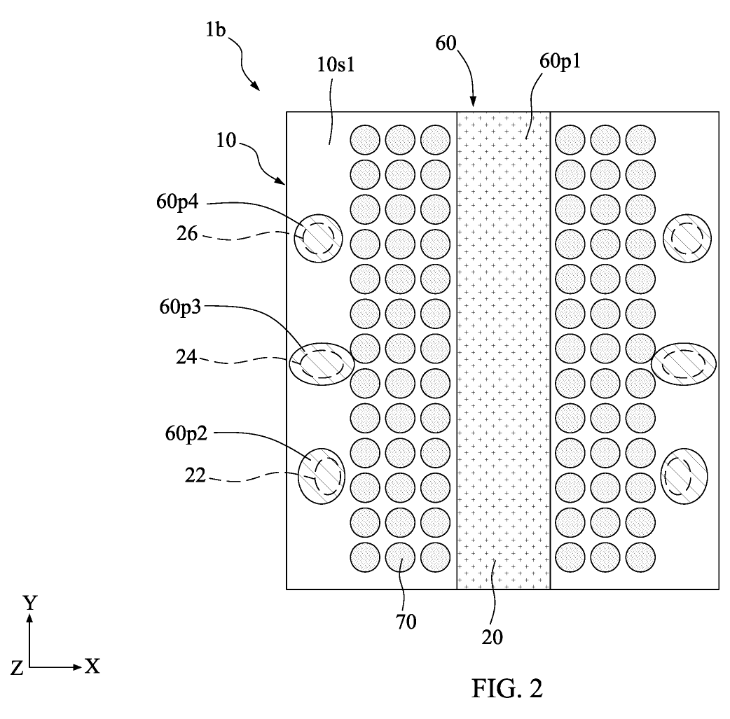

FIG. 2 is a bottom view of a semiconductor device 1b, in accordance with some embodiments of the present disclosure.

In some embodiments, the electrical connectors 70 may be arranged between the opening 22 (or opening 24 or 26) and the opening 20 along the X direction. In some embodiments, the opening 22 (or opening 24 or 26) may be free from overlapping the electrical connectors 70 along the Y direction. In some embodiments, the opening 22 may overlap the opening 24 along the Y direction. In some embodiments, the opening 22 may overlap the opening 20 along the X direction.

In some embodiments, a portion 60p3 of the encapsulant 60 may be disposed within the opening 24. In some embodiments, the electronic component 30 may partially overlap the portion 60p3. In some embodiments, a portion 60p4 of the encapsulant 60 may be disposed within the opening 26. In some embodiments, the electrical connectors 70 may be disposed between the portion 60p1 and the portion 60p2 along the X direction.

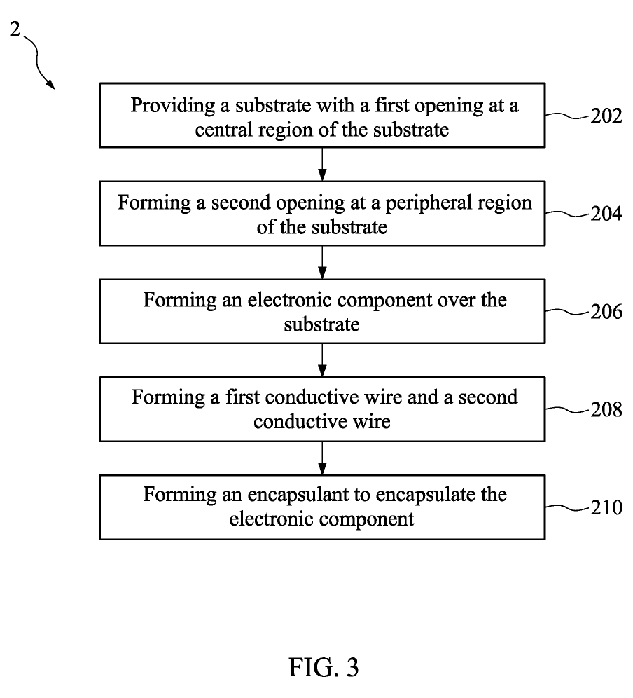

FIG. 3 is a flowchart illustrating a method 3 of manufacturing a semiconductor device, in accordance with some embodiments of the present disclosure.

The method 2 begins with an operation 202 in which a substrate may be provided. The substrate may have a central region and a peripheral region. A first opening (or slot) may be formed at the central region. The substrate has a lower surface and an upper surface opposite to the lower surface.

The substrate includes a first pad at the central region and configured to transmit a non-power signal.

The substrate includes a second pad at the peripheral region and configured to transmit a power signal or non-power signal.

The method 2 continues with an operation 204 in which a second opening may be formed at the peripheral region of the substrate. The second opening abuts the second pad.

A third opening (or slot) may be formed at the peripheral region of the substrate. The third opening may have an area different from that of the second opening. The third opening may have a profile different from that of the second opening.

The method 2 continues with an operation 206 in which an electronic component may be formed on the substrate. The electronic component includes a first pad exposed by the first opening and a second pad exposed by the second opening.

The method 2 continues with an operation 208 in which a first conductive wire may be formed to electrically connect the first pad of the electronic component and the first pad of the substrate through the first opening and a second conductive wire may be formed to electrically connect the second pad of the electronic component and the second pad of the substrate through the second opening.

The method 2 continues with an operation 210 in which an encapsulant may be formed to encapsulate the electronic component. The encapsulant may fill the first opening and the second opening. Electrical connectors may be formed. As a result, a semiconductor device may be produced.

The electrical connectors may be formed between the first slot and the second slot along a first direction. The second slot may be free from overlapping the electrical connectors along a second direction orthogonal to the first direction. The second opening may overlap the third opening along the second direction.

The method 2 is merely an example, and is not intended to limit the present disclosure beyond what is explicitly recited in the claims. Additional operations can be provided before, during, or after each operation of the method 2, and some operations described can be replaced, eliminated, or reordered for additional embodiments of the method. In some embodiments, the method 2 can include further operations not depicted in FIG. 3. In some embodiments, the method 2 can include one or more operations depicted in FIG. 3.

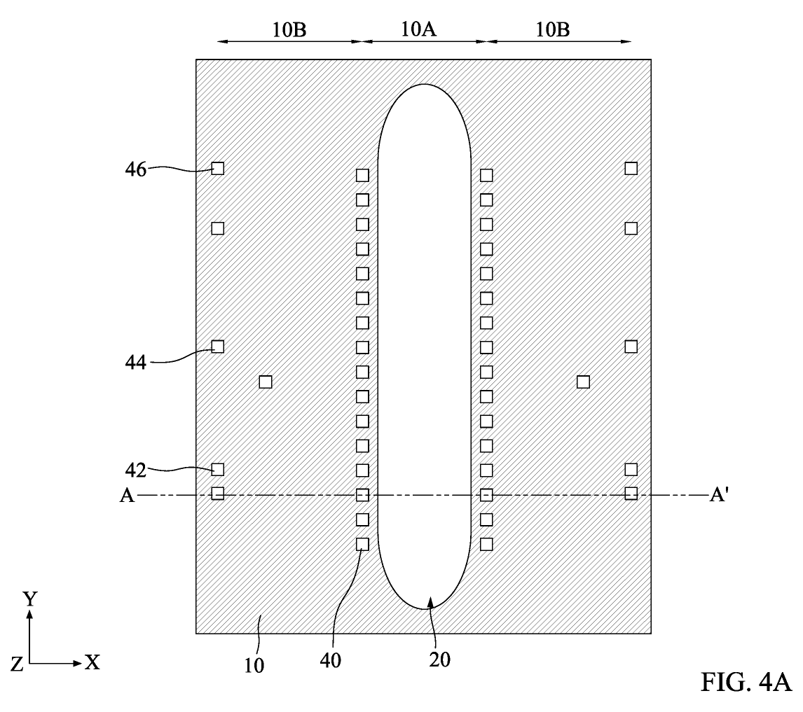

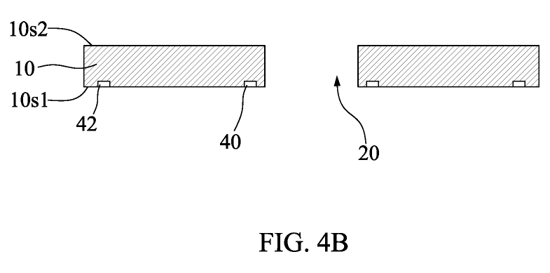

FIG. 4A-FIG. 8A illustrate one or more stages of an exemplary method for manufacturing a semiconductor device according to some embodiments of the present disclosure. FIG. 4B-FIG. 8B are cross-sectional views along line A-A' of FIG. 4A-FIG. 8A, respectively. In some embodiments, the semiconductor device 1a may be manufactured through the operations described with respect to FIG. 4A-FIG. 8A.

Referring to FIG. 4A and FIG. 4B, the substrate 10 may be provided. The substrate 10 may have the central region 10A and the peripheral region 10B. The opening 20 may be formed at the central region 10A of the substrate 10. The substrate 10 may have the pads 40, 42, 44, and 46. The pad 40 may be disposed within the central region 10A and configured to transmit a non-power signal. The pads 42, 44, and 46 may be disposed within the peripheral region 10B and configured to transmit a power signal or non-power signal.

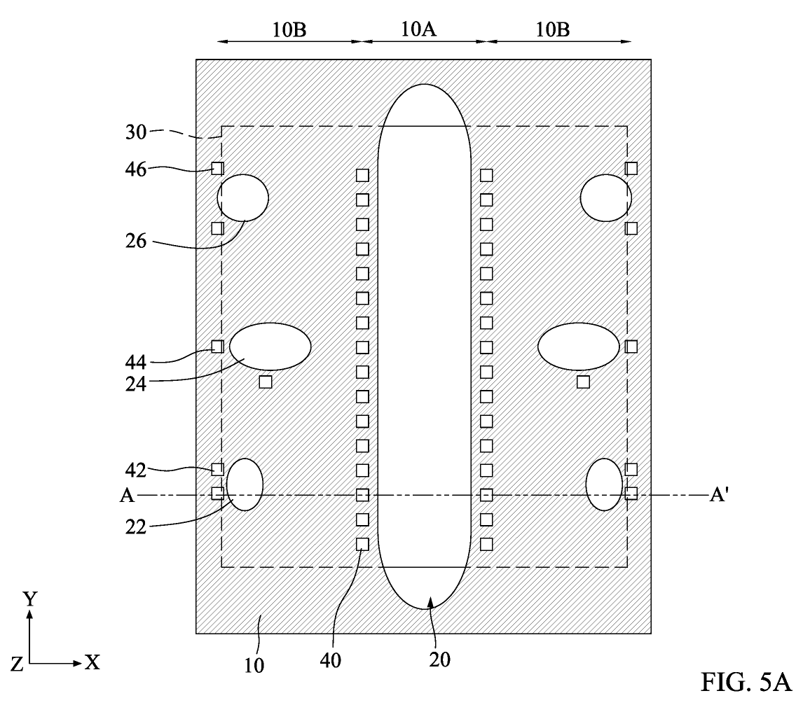

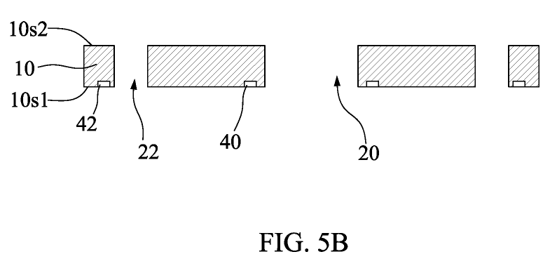

Referring to FIG. 5A and FIG. 5B, the openings 22, 24, and 26 may be formed at the peripheral region 10B of the substrate 10.

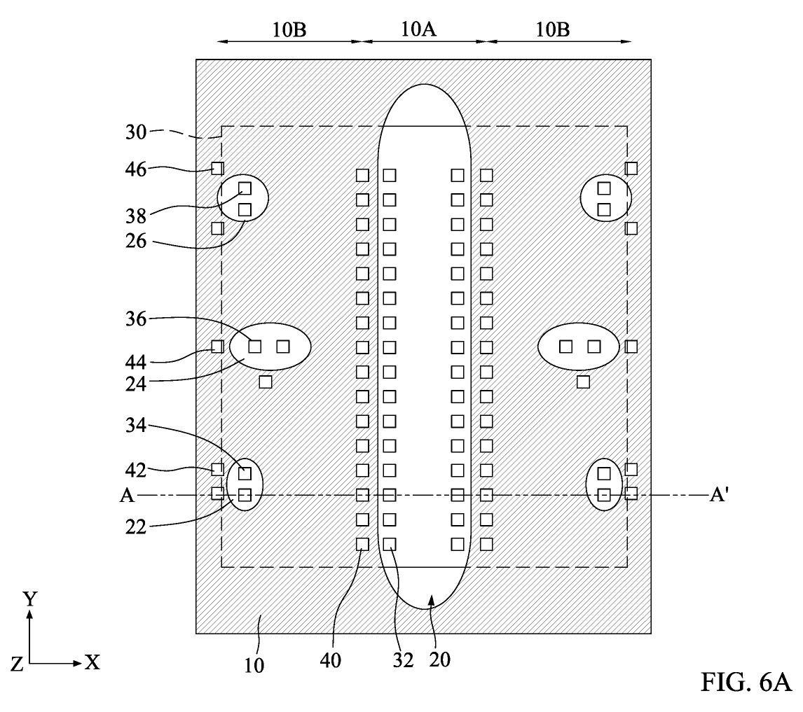

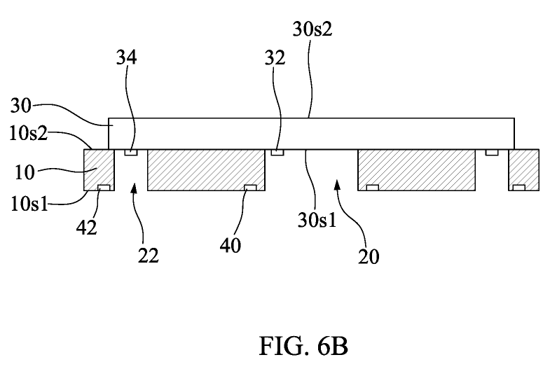

Referring to FIG. 6A and FIG. 6B, the electronic component 30 may be formed on or over the surface 10s2 of the substrate 10. The pad 32 may be exposed by the opening 20. The pad 34 may be exposed by the opening 22. The pad 36 may be exposed by the opening 24. The pad 38 may be exposed by the opening 26.

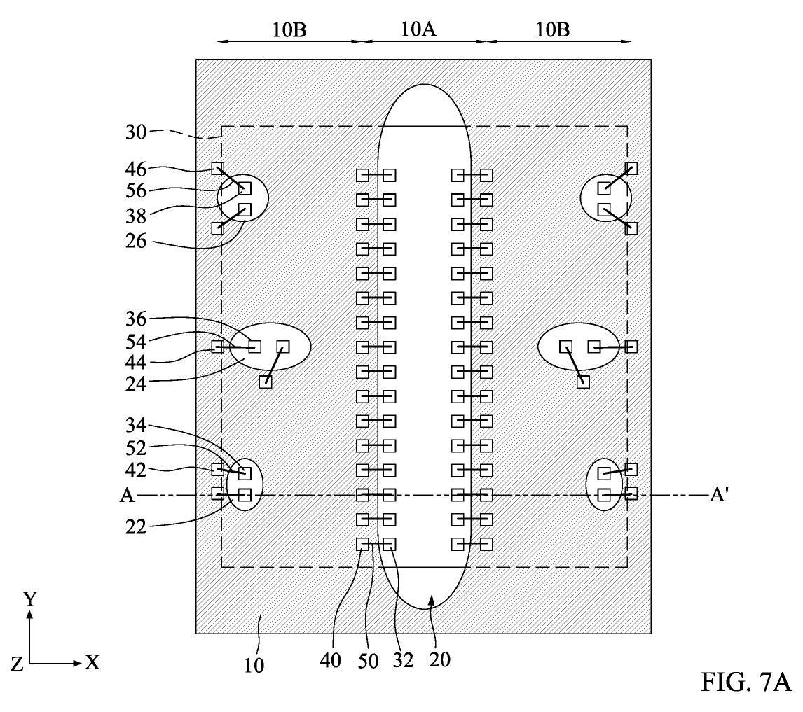

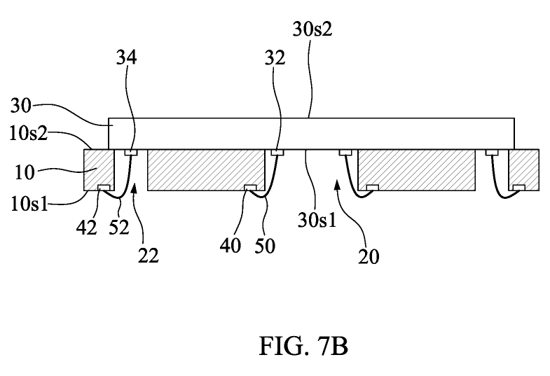

Referring to FIG. 7A and FIG. 7B, the conductive wire 50 may be formed to electrically connect the pad 32 and the pad 40 through the opening 20. The conductive wire 52 may be formed to electrically connect the pad 34 and the pad 42 through the opening 22. The conductive wire 54 may be formed to electrically connect the pad 36 and the pad 44 through the opening 24. The conductive wire 56 may be formed to electrically connect the pad 38 and the pad 46 through the opening 26.

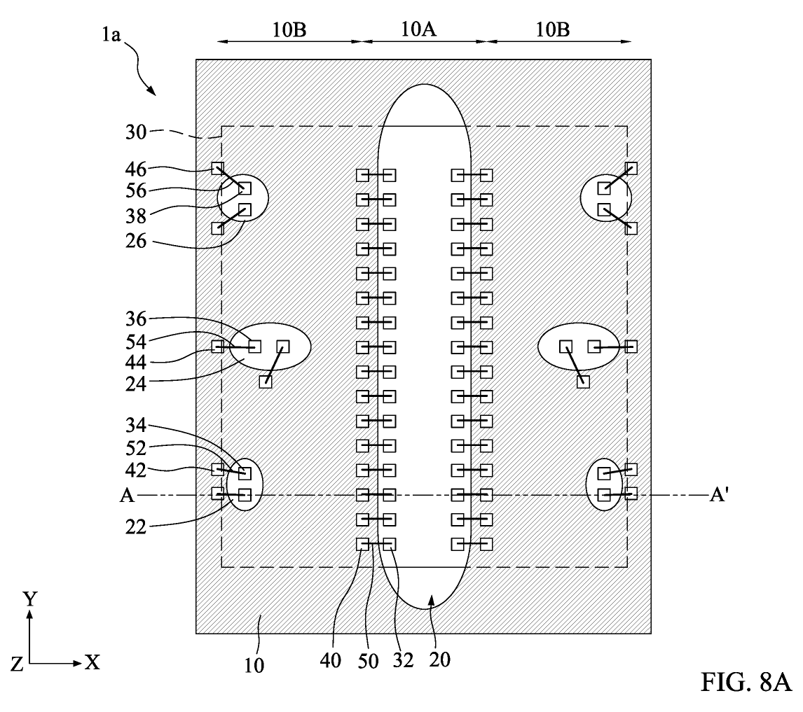

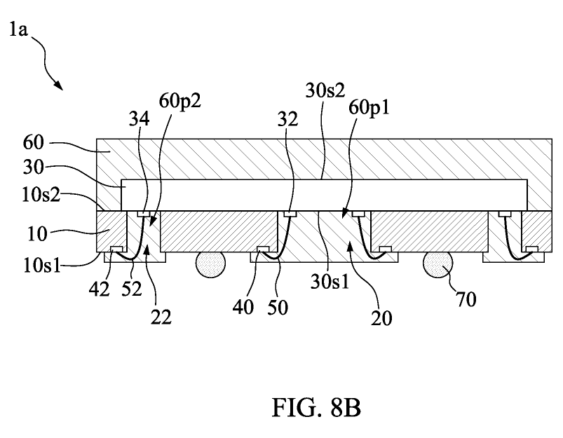

Referring to FIG. 8A and FIG. 8B, the encapsulant 60 may be formed to encapsulate the electronic component 30. The encapsulant 60 may fill the openings 20, 22, 24, and 26. The electrical connectors 70 may be formed on or under the surface 10s1 of the substrate 10. As a result, a semiconductor device (e.g., the semiconductor device 1a) may be produced.

One aspect of the present disclosure provides a semiconductor device. The semiconductor device includes a substrate, an electronic component, and an encapsulant. The substrate has a lower surface and an upper surface opposite to the lower surface. The electronic component is disposed on the upper surface of the substrate. The encapsulant is disposed on the upper surface of the substrate. The encapsulant includes a first portion penetrating the substrate at a central region of the substrate and a second portion penetrating the substrate at a peripheral region of the substrate.

Another aspect of the present disclosure provides another semiconductor device. The semiconductor device includes a substrate, an electronic component, a first pad, a second pad, a first conductive wire, and a second conducive wire. The substrate has a lower surface and an upper surface opposite to the lower surface. The first pad is disposed on the lower surface and at a central region of the substrate. The second pad is disposed on the lower surface and at a peripheral region of the substrate. The electronic component is disposed on the upper surface of the substrate. The first conductive wire passes through the central region of the substrate to electrically connect the electronic component and the first pad. The second conductive wire passes through the peripheral region of the substrate to electrically connect the electronic component and the second pad.

Another aspect of the present disclosure provides a method of manufacturing a semiconductor device. The method includes: providing a substrate having a lower surface and an upper surface opposite to the first surface, wherein the substrate has a first slot at a central region and a second slot at a peripheral region of the substrate; forming an electronic component on the upper surface of the substrate; and forming an encapsulant to encapsulate the electronic component, and the encapsulant has a first portion filling the first slot and a second portion filling the second slot.

In an advantageous semiconductor device, power pads are arranged at the peripheral region of a substrate. To reduce the power path and address packaging issues, one or more slots can be formed on the peripheral region of the substrate. The locations of the slots depend on the location of the power pads. In this embodiment, the process is relatively simple, and the power path can be reduced, resulting in enhanced performance of the semiconductor device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate having a lower surface and an upper surface opposite to the lower surface;
an electronic component disposed on the upper surface of the substrate; and
an encapsulant disposed on the upper surface of the substrate, wherein the encapsulant comprises a first portion penetrating the substrate at a central region of the substrate and a second portion penetrating the substrate at a peripheral region of the substrate.

2. The semiconductor device of claim 1, wherein a first area of the first portion is greater than a second area of the second portion of the encapsulant.

3. The semiconductor device of claim 1, wherein the electronic component vertically overlaps the first portion of the encapsulant.

4. The semiconductor device of claim 3, wherein the electronic component vertically overlaps the second portion of the encapsulant.

5. The semiconductor device of claim 1, further comprising:
a first conductive wire passing through the first portion of the encapsulant and electrically connecting the electronic component and a first pad of the substrate; and
a second conductive wire passing through the second portion of the encapsulant and electrically connecting the electronic component and a second pad of the substrate.

6. The semiconductor device of claim 5, wherein the first pad is configured to transmit a non-power signal.

7. The semiconductor device of claim 5, wherein the second pad is configured to transmit a power signal.

8. The semiconductor device of claim 5, wherein the second pad is configured to transmit a non-power signal.

9. The semiconductor device of claim 1, further comprising:
a plurality of electrical connectors disposed on the lower surface of the substrate, wherein the plurality of electrical connectors are arranged between the first portion and the second portion of the encapsulant along a first direction.

10. The semiconductor device of claim 9, wherein the second portion of the encapsulant is free from overlapping the plurality of electrical connectors along a second direction substantially orthogonal to the first direction.

11. The semiconductor device of claim 1, wherein the second portion of the encapsulant is partially free from vertically overlapping the electronic component.

12. A semiconductor device, comprising:
a substrate having a lower surface and an upper surface opposite to the lower surface;
a first pad disposed on the lower surface and at a central region of the substrate;
a second pad disposed on the lower surface and at a peripheral region of the substrate;
an electronic component disposed on the upper surface of the substrate;
a first conductive wire passing through the central region of the substrate to electrically connect the electronic component and the first pad; and
a second conductive wire passing through the peripheral region of the substrate to electrically connect the electronic component and the second pad.

13. The semiconductor device of claim 12, wherein the first pad is configured to transmit a non-power signal.

14. The semiconductor device of claim 12, wherein the second pad is configured to transmit a power signal.

15. The semiconductor device of claim 12, wherein the second pad is configured to transmit a non-power signal.

16. The semiconductor device of claim 12, wherein the substrate defines a first slot at the central region and a second slot at the peripheral region.

17. The semiconductor device of claim 16, further comprising:
an encapsulant filling the first slot and the second slot.

18. The semiconductor device of claim 16, wherein a first area of the first slot is greater than a second area of the second slot of the substrate.

19. The semiconductor device of claim 16, wherein the electronic component vertically overlaps the first slot and the second slot of the substrate.

20. The semiconductor device of claim 18, wherein the substrate further defines a third slot at the peripheral region, and a third area of the third slot is different from the second area of the second slot of the substrate.
